(19) United States
(12) Patent Application Publication
(10) Pub. No.: US 2025/0317126 A1
(43) Pub. Date: Oct. 9, 2025

(54) DIFFERENTIAL TO SINGLE ENDED BALUN TECHNIQUE

(71) Applicant: Skyworks Solutions, Inc., Irvine, CA (US)

(72) Inventor: Leslie Paul Wallis, Ottawa (CA)

(21) Appl. No.: 19/170,243

(22) Filed: Apr. 4, 2025

Related U.S. Application Data
(60) Provisional application No. 63/631,625, filed on Apr. 9, 2024.

(51) Int. Cl. H03H 11/32; H03F 3/24

(52) U.S. Cl. CPC H03H 11/32; H03F 3/245

(57) ABSTRACT

A system including a low loss balun is presented, the system including an amplifier; an antenna; a reference node; a first winding coupled between the antenna and the amplifier; and a second winding electromagnetically coupled to the first winding and coupled between the reference node and the amplifier.

### CROSS-REFERENCE TO RELATED APPLICATIONS

This application claims priority under 35 U.S.C. § 119 (e) to U.S. Provisional Patent Application No. 63/631,625, titled DIFFERENTIAL TO SINGLE ENDED BALUN TECHNIQUE, filed on Apr. 9, 2024, which is hereby incorporated by reference in its entirety for all purposes.

### BACKGROUND

### 1. Field of the Disclosure

At least one example in accordance with the present disclosure relates generally to balun transformers.

### 2. Discussion of Related Art

Baluns are devices used to take balanced inputs and convert them to unbalanced outputs, or to convert unbalanced inputs into balanced outputs.

### SUMMARY

According to at least one aspect of the present disclosure a system with a low loss balun is presented, the system comprising an amplifier; an antenna; a reference node; a first winding coupled between the antenna and the amplifier; and a second winding electromagnetically coupled to the first winding and coupled between the reference node and the amplifier.

In some examples, the system further comprises a third winding coupled between a first end of the first winding and a first end of the second winding. In some examples, the system further comprises a fourth winding coupled in series with the third winding between the first end of the first winding and the first end of the second winding. In some examples, the reference node is further coupled between the third winding and the fourth winding. In some examples, the system further comprises a second amplifier; a third winding coupled between the antenna and the second amplifier; and a fourth winding electromagnetically coupled to the first winding and coupled between the reference node and the second amplifier. In some examples, the amplifier, antenna, reference node, first winding, and second winding are part of a transmit path. In some examples, the second amplifier, third winding, fourth winding, reference node, and antenna are part of a receive path. In some examples, the first winding has a length of one-quarter a wavelength of a signal provided to the antenna, and the second winding has a length of one-quarter the wavelength. In some examples, no series switches are interposed between the first winding and the antenna. In some examples, no shunt switches are interposed between the first winding and the antenna.

According to at least one aspect of the present disclosure, a system with a low loss balun is presented, the system comprising a transmit path having a first amplifier, an antenna, a first winding coupled at one end to a first output of the first amplifier and at another end to the antenna, a second winding electromagnetically coupled to the first winding and coupled at one end to a second input of the amplifier and at another end to a reference node; and a receive path having a second amplifier, a third winding coupled at one end to a first input of the second amplifier and at another end to the antenna, and a fourth winding electromagnetically coupled to the third winding and coupled at one end to a second input of the second amplifier and at another end to the reference node.

In some examples, the system further comprises a first filter coupled between the first output and the first winding, and a second filter coupled between the second output and the second winding. In some examples, the system further comprises a third filter coupled between the first input and the third winding, and a fourth filter coupled between the second input and the fourth winding. In some examples, the system further comprises a fifth winding and a sixth winding, the fifth winding coupled to the first winding at one end and to the sixth winding at another end, and the sixth winding coupled to the second winding at one end and to the fifth winding at another end. In some examples, the system further comprises a seventh winding and an eighth winding, the seventh winding coupled at one end to the third winding and at another end to the eighth winding, and the eighth winding coupled at one end to the fourth winding and at another end to the seventh winding. In some examples, the reference node is further coupled between the fifth winding and sixth winding. In some examples, the reference node is further coupled between the seventh winding and the eighth winding. In some examples, no series switches are interposed between the first winding and the antenna. In some examples, no shunt switches are interposed between the first winding and the antenna.

According to at least one aspect of the present disclosure, a system having a low loss balun is presented, the system comprising a first amplifier having a first connection and a second connection; a second amplifier having a third connection and a fourth connection; an antenna; a first winding coupled between the first connection and the antenna; a second winding coupled between the second connection and a reference node; a third winding coupled between the third connection and the antenna; and a fourth winding coupled between the fourth connection and the reference node, there being no switches in series or shunt configuration interposed between the antenna and either of the first winding and third winding.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a low loss balun according to an example;

FIG. 2 illustrates a low loss balun according to an example;

FIG. 3 illustrates a transmit path according to an example;

FIG. 4 illustrates a receive path according to an example;

FIG. 5 illustrates a transmit path according to an example; and

FIG. 6 illustrates a receive path according to an example.

### DETAILED DESCRIPTION

According to aspects of this disclosure, signal transmission and processing systems (such as those used in telecommunications) may include antennas used to transmit and/or receive signals. Such antennas may be coupled to or incorporated in a receiver, transmitter, or transceiver, for example, as part of a front-end module (FEM) of a telecommunications device.

The antenna may require power when transmitting the signal, and may require amplification when receiving the signal. For example, when transmitting a signal, the effective range of the signal (before it is drowned by background noise) may depend proportionally on the power used to transmit the signal, with higher power generally equating to a longer transmission range. A power amplifier (PA) may be used to amplify the desired signal. Likewise, when receiving signals, amplification may be used to boost the signal so that the signal may be more readily differentiated from background noise (e.g., random electromagnetic noise, or other signals). When amplifying a received signal, a low noise amplifier (LNA) may be used to amplify the desired signal while not amplifying (or not amplifying as much) background noise.

In some topologies discussed herein, a PA/LNA system may include a differential amplifier accompanied by a series of switches (for example, a series of one or more switch-pairs) to route a signal to the antenna or to receive a signal from the antenna. The switches may be arranged in series and/or in shunt (where shunt means the switches or a subset of the switches are connected to a reference node and/or ground). The switches may cause losses that degrade gain provided to the signal, e.g., insertion loss. Likewise, a balun (a device that interfaces balanced and unbalanced lines without significantly affecting the impedance arrangement of the lines) may suffer from similar losses. That is, both the switches and/or the balun may degrade gain, reduce power efficiency, and receive and/or cause noise.

In some topologies discussed herein, a quarter wavelength transmission line may be used to create an open circuit at the antenna end by short circuiting the other end of the line.

However, in accordance with aspects of the present disclosure, both the quarter wavelength transmission line approach and the PA/LNA system with differential amplification and multiple switches may be replaced with a low loss balun that performs the same function and provides a substantial improvement in performance (corresponding to an approximately 1.5 dB improvement in loss and/or a reduction in power supply current of 25%, 28%, 30%, or more).

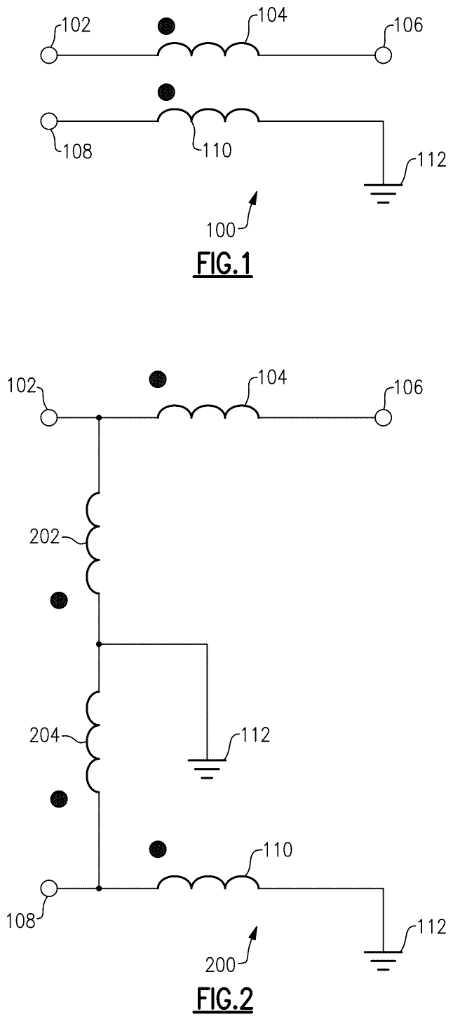

FIG. 1 illustrates a low loss balun 100 (“balun 100”) according to an example. The balun 100 includes a first differential input 102, a first coil or winding 104, an output 106, a second differential input 108, a second coil or winding 110, and a reference voltage connection 112 (“ground 112”). The balun 100 may convert a differential input into a single-ended output. That is, the balun 100 may receive an input at the first differential input 102 and/or the second differential input 108 (possibly alternating between the inputs, and possibly according to a duty cycle). But, because the second coil or winding 110 is coupled to ground 112 (as will be discussed below), the signal corresponding to the second winding 110 is not transmitted. Instead, the signal corresponding to the first winding 104, which is coupled to the output 106, is transmitted. Likewise, when receiving a signal at the output 106, the signal may be converted from a single-ended signal to a differential signal because the current through the first winding 104 may induce a current through the second winding 110, and both those currents (and their corresponding voltages) may be provided to the respective first differential input 102 or second differential input 108. Thus, the balun 100 provides a method for converting single-ended signals into differential signals, and differential signals into single-ended signals.

The first winding 104 is coupled at a first end to the first differential input 102 and at a second end to the output 106. The second winding 110 is coupled to the second differential input 104 at a first end, and to the ground 112 at a second end.

The first differential input 102 and the second differential input 108 are configured to receive signal inputs from the system or to provide signal inputs to the system. That is, the first differential input 102 may be configured to provide a signal to the first coil 104 or to receive a signal from the first coil 104, and the second differential input 108 may be configured to provide a signal to the second coil 110 or receive a signal from the second coil 110.

The output 106 may be coupled to an antenna or other output device, and may thus be used to provide signals for transmission (for example, provide said signals to an antenna) or receive signals that were transmitted (for example, receive signals from an antenna and provide those signals to the first coil 104).

The ground 112 may be a connection to a reference voltage (for example, a voltage considered to have a value of zero relative to the other voltages in the balun 100 or the system to which the balun 100 is coupled).

In some examples, the first winding 104 and the second winding 110 may be electromagnetically coupled together, such that a current through the first winding 104 induces a current through the second winding 110, and a current through the second winding 110 induces a current through the first winding 104. It will be understood by those of skill in the art that, when referring to currents in one winding inducing currents in another winding, the currents will typically vary with time. Alternatively, the currents may be replaced with voltages, for example, voltages that generally vary with time.

FIG. 2 illustrates a low loss balun 200 (“balun 200”) according to an example. The balun 200 includes a first differential input 102, a first winding 104, an output 106, a second differential input 108, a second winding 110, a reference voltage connection 112 (“ground 112”), a third winding 202, and a fourth winding 204.

The balun 200 operates in a similar manner to the balun 100 of FIG. 1. The differential inputs 102, 108 may receive input signals and provide them to the first and/or second winding 104, 110, before outputting a single-ended output at the output 106. Likewise, when a signal is received at the output 106, it can be provided to the first winding 104, which can induce a signal on the second winding 110. Those signals can then be provided to the first differential input 102 or the second differential input 108, respectively. Like the balun 100, the differential input signal provided to the first differential input 102 and second differential input 108 may alternate in time or be provided according to a duty cycle, and so forth.

In some examples, the balun 200 includes all the functionality of the balun 100 of FIG. 1. However, the balun 200 can add various additional features compared to the balun 100 of FIG. 1. The balun 200 effectively connects the first differential input 102 and the second differential input 108 via the third inductor 202 and fourth inductor 204 such that the first conducting path between the first differential input 102, first winding 104, and output 108, and the second conducting path between the second differential input 108, second winding 110, and ground 112, are now in parallel with one another. This parallel topology improves the Q-factor of the circuit. Additionally, the impedance of an antenna (e.g., the antenna coupled to the output 106) may be improved.

In FIG. 2, all elements also present in FIG. 1 are coupled together as described with respect to FIG. 1. Additionally, the third inductor 202 is coupled at one end to the first differential input 102 and first winding 104, and at the other end to the fourth winding 204 and ground 112. The fourth winding 204 is coupled at one end to the second differential input 108 and the second winding 110, and at the other end to the third winding 202 and ground 112. The ground connection 112 located between the third winding 202 and fourth winding 204 ensures that signals transmitted across the third or fourth windings 202, 204 from the inputs 102, 108 or first and second windings 104, 110 are routed to ground. That is, signals on the first conducting path will be routed to ground instead of appearing on the second conducting path, and signals on the second conducting path will be routed to ground instead of appearing on the first conducting path. Note that signals induced on the first and second windings 104, 110 by the other of the first and second windings 104, 110 will not necessarily be routed to ground. However, signals which are routed across the third and/or fourth inductors 202, 204 may be routed to ground 112.

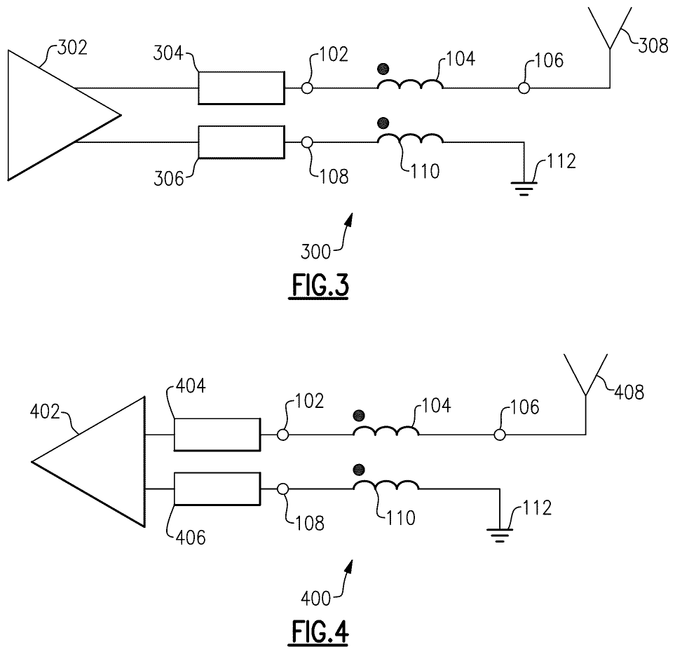

In some examples, the windings may be formed by transmission lines, especially at higher frequencies. In such examples, the lengths of the baluns 100, 200 may be important. For example, the length of the conducting paths (e.g., the first and second conducting paths) may be set to some fraction (greater than, equal to, or lesser than 1) of the wavelength of the signals being received. For example, 1/10^{th}, ⅛^{th}, ⅙^{th}, ¼^{th}, ⅓^{rd}, ½, 1, 2, and so forth. In some examples, the electrical length of the first and second windings 104, 110 may be a quarter wavelength, and the topology of the balun 200 may offer improved performance by, for example, improving the Q-factor and/or the impedance seen by the antenna. In some embodiments, as illustrated, two sets of windings may be used, such that one is used for the transmit path and the other is used for the receive path. For example, the balun 300 of FIG. 3 may be used for a transmit path and the balun 400 of FIG. 4 may be used for the receive path in a device.

FIG. 3 illustrates a differential output path 300 (e.g., for the transmit path of a front-end module) according to an example. The differential output path 300 includes a power amplifier 302, a first filter block 304, a second filter block 306, an antenna 308, and the balun 100 of FIG. 1.

The power amplifier 302 has a differential output and may have a differential input. A first differential output of the power amplifier 302 is coupled to the first filter block 304. A second differential output of the power amplifier 302 is coupled to the second filter block 306. The first filter block 304 is coupled to the first differential input 102. The second filter block 306 is coupled to the second differential input 108. The output 106 is coupled to the antenna 308.

The power amplifier 302 amplifies an input signal (or differential input signal) and provides a first differential output signal to the first filter block 304 and a second differential output signal to the second filter block 306. The first filter block 304 may include one or more circuit elements, including resistors, capacitors, inductors, diodes, transistors, and so forth, and may be configured to adjust characteristics of the first differential output signal, such as harmonics, frequency components, amplitudes, and so forth. The second filter block 306 may include one or more circuit elements, including resistors, capacitors, inductors, diodes, transistors, and so forth, and may be configured to adjust characteristics of the second differential output signal, such as harmonics, frequency components, amplitudes, and so forth.

The balun in the differential output path 300 operates as described above: signals based on the first differential output signal and/or second differential output signal are induced and/or present on the first winding 104 and second winding 110. The signals (whether induced or not) on the first winding 104 are provided to the output 106, and then to the antenna 308.

FIG. 4 illustrates a differential input path 400 (e.g., the receive path of a front end module) according to an example. The differential input path 400 includes a low-noise amplifier 402 (“LNA 402”), a first filter block 404, a second filter block 406, an antenna 408, and the balun 100 of FIG. 1.

A first input of the LNA 402 is coupled to the first filter block 404. A second input of the LNA 402 is coupled to the second filter block 406. The first filter block 404 is coupled to the first differential input 102. The second filter block 406 is coupled to the second differential input 108. The output 106 is coupled to the antenna 408.

The first filter block 404 may include one or more circuit elements, including resistors, capacitors, inductors, diodes, transistors, and so forth, and may be configured to adjust characteristics of the first differential output signal, such as harmonics, frequency components, amplitudes, and so forth. The second filter block 406 may include one or more circuit elements, including resistors, capacitors, inductors, diodes, transistors, and so forth, and may be configured to adjust characteristics of the second differential output signal, such as harmonics, frequency components, amplitudes, and so forth.

The antenna 408 is configured to receive a signal and provide the signal to the output 106. The output may provide the signal to the first winding 104 and thence to the first differential input 102, the first filter block 404 may receive the signal and modify it, and the signal may be provided to the LNA 402 to be amplified. An induced signal on the second winding 110 may also be present and may be directed to ground or directed to the second differential input 108, the second filter block 406, and then to the LNA 402 where it may be amplified.

The LNA 402 may have a single-ended output or a differential output.

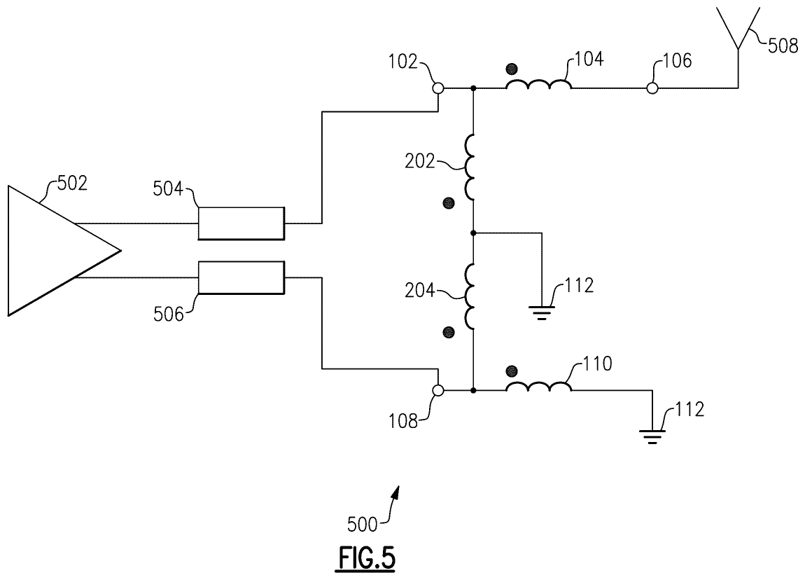

FIG. 5 illustrates a differential output path 500 (e.g., for the transmit path of a front-end module) according to an example. The differential output path 500 includes a power amplifier 502, a first filter block 504, a second filter block 506, an antenna 508, and the balun 200 of FIG. 2.

The power amplifier 502 has a differential output and may have a differential input. A first differential output of the power amplifier 502 is coupled to the first filter block 504. A second differential output of the power amplifier 502 is coupled to the second filter block 506. The first filter block 504 is coupled to the first differential input 102. The second filter block 506 is coupled to the second differential input 108. The output 106 is coupled to the antenna 508.

The power amplifier 502 amplifies an input signal (or differential input signal) and provides a first differential output signal to the first filter block 504 and a second differential output signal to the second filter block 506. The first filter block 504 may include one or more circuit elements, including resistors, capacitors, inductors, diodes, transistors, and so forth, and may be configured to adjust characteristics of the first differential output signal, such as harmonics, frequency components, amplitudes, and so forth. The second filter block 506 may include one or more circuit elements, including resistors, capacitors, inductors, diodes, transistors, and so forth, and may be configured to adjust characteristics of the second differential output signal, such as harmonics, frequency components, amplitudes, and so forth.

The balun of the differential output path 500 operates as described above: signals based on the first differential output signal and/or second differential output signal are induced and/or present on the first winding 104 and second winding 110. The signals (whether induced or not) on the first winding 104 are provided to the output 106, and then to the antenna 508.

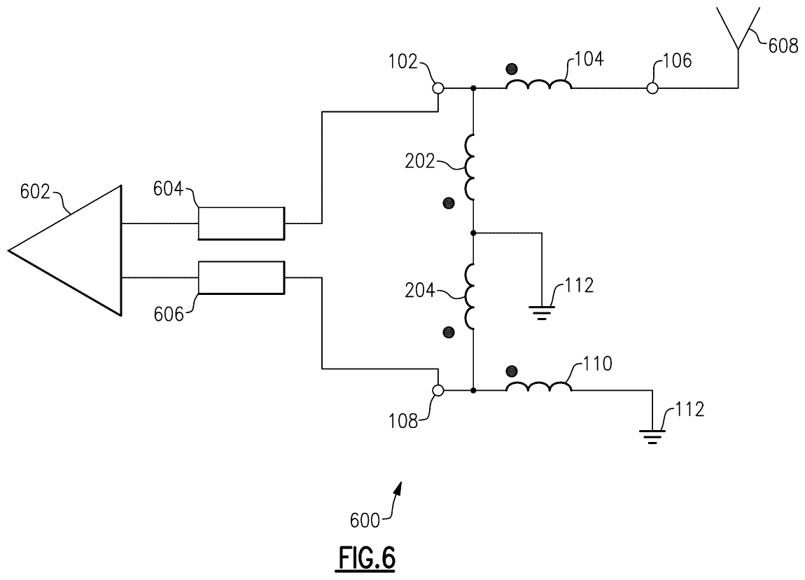

FIG. 6 illustrates a differential input path 600 (e.g., the receive path of a front end module) according to an example. The differential input path 600 includes a low-noise amplifier 602 (“LNA 602”), a first filter block 604, a second filter block 606, an antenna 608, and the balun 200 of FIG. 2.

A first input of the LNA 602 is coupled to the first filter block 604. A second input of the LNA 602 is coupled to the second filter block 606. The first filter block 604 is coupled to the first differential input 102. The second filter block 606 is coupled to the second differential input 108. The output 106 is coupled to the antenna 608.

The first filter block 604 may include one or more circuit elements, including resistors, capacitors, inductors, diodes, transistors, and so forth, and may be configured to adjust characteristics of the first differential output signal, such as harmonics, frequency components, amplitudes, and so forth. The second filter block 606 may include one or more circuit elements, including resistors, capacitors, inductors, diodes, transistors, and so forth, and may be configured to adjust characteristics of the second differential output signal, such as harmonics, frequency components, amplitudes, and so forth.

The antenna 608 is configured to receive a signal and provide the signal to the output 106. The output may provide the signal to the first winding 104 and thence to the first differential input 102, the first filter block 404 may receive the signal and modify it, and the signal may be provided to the LNA 602 to be amplified. An induced signal on the second winding 110 may also be present and may be directed to ground or directed to the second differential input 108, the second filter block 606, and then to the LNA 402 where it may be amplified.

The LNA 602 may have a single-ended output or a differential output.

In some embodiments, as illustrated, multiple sets of windings may be used, such that one is used for the transmit path and the other is used for the receive path. For example, the balun of FIG. 5 may be used for a transmit path and the balun of FIG. 6 may be used for the receive path in a device. Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A system comprising:
an amplifier;
an antenna;
a reference node;
a first winding coupled between the antenna and the amplifier;
a second winding electromagnetically coupled to the first winding and coupled between the reference node and the amplifier; and
a third winding and a fourth winding coupled in series with one another and coupled between a first end of the first winding and a first end of the second winding.

2. The system of claim 1 wherein the amplifier is either a power amplifier or a low noise amplifier.

3. The system of claim 1 further comprising a first filter coupled between the first winding and the amplifier, and a second filter coupled between the second winding and the amplifier.

4. The system of claim 1 wherein the reference node is further coupled between the third winding and the fourth winding.

5. The system of claim 1 further comprising:
a second amplifier;
a fifth winding coupled between the antenna and the second amplifier; and
a sixth winding electromagnetically coupled to the first winding and coupled between the reference node and the second amplifier.

6. The system of claim 5 wherein the amplifier, antenna, reference node, first winding, and second winding are part of a transmit path.

7. The system of claim 6 wherein the second amplifier, fifth winding, sixth winding, reference node, and antenna are part of a receive path.

8. The system of claim 1 wherein the first winding has a length of one-quarter a wavelength of a signal provided to the antenna, and the second winding has a length of one-quarter the wavelength.

9. The system of claim 1 wherein no series switches are interposed between the first winding and the antenna.

10. The system of claim 1 wherein no shunt switches are interposed between the first winding and the antenna.

11. A system comprising:
a transmit path having
a first amplifier,
an antenna,
a first winding coupled at one end to a first output of the first amplifier and at another end to the antenna,
a second winding electromagnetically coupled to the first winding and coupled at one end to a second output of the amplifier and at another end to a reference node, and
one or more additional transmit path windings coupled between a first connection of the first winding and a first connection of the second winding, and coupled to the reference node; and
a receive path having
a second amplifier,
a third winding coupled at one end to a first input of the second amplifier and at another end to the antenna,
a fourth winding electromagnetically coupled to the third winding and coupled at one end to a second input of the second amplifier and at another end to the reference node, and
one or more additional receive path windings coupled between a first connection of the third winding and a first connection of the second winding, and coupled to the reference node.

12. The system of claim 11 further comprising a first filter coupled between the first output and the first winding, and a second filter coupled between the second output and the second winding.

13. The system of claim 12 further comprising a third filter coupled between the first input and the third winding, and a fourth filter coupled between the second input and the fourth winding.

14. The system of claim 11 wherein the first amplifier is a power amplifier.

15. The system of claim 14 wherein the second amplifier is a low noise amplifier.

16. The system of claim 11 wherein the reference node is coupled between a first additional winding of the one or more transmit path windings and a second additional winding of the one or more transmit path windings.

17. The system of claim 16 wherein the reference node is coupled between a first additional winding of the one or more receive path windings and a second additional winding of the one or more receive path windings.

18. The system of claim 11 wherein no series switches are interposed between the first winding and the antenna.

19. The system of claim 11 wherein no shunt switches are interposed between the first winding and the antenna.

20. A system comprising:
a first amplifier having a first connection and a second connection;
a second amplifier having a third connection and a fourth connection;
an antenna;
a first winding coupled between the first connection and the antenna;
a second winding coupled between the second connection and a reference node;
a third winding coupled between the third connection and the antenna; and
a fourth winding coupled between the fourth connection and the reference node, there being no switches in series or shunt configuration interposed between the antenna and either of the first winding and third winding.
